(19) United States
(12) Patent Application Publication
(10) Pub. No.: US 2011/0214708 A1
(43) Pub. Date: Sep. 8, 2011

(54) SOLAR CELL MODULE AND SOLAR CELL DEVICE

(75) Inventor: Haruo YAGO, Kanagawa (JP)

(73) Assignee: FUJIFILM CORPORATION, Tokyo (JP)

(21) Appl. No.: 13/038,064

(22) Filed: Mar. 1, 2011

(30) Foreign Application Priority Data
Mar. 2, 2010 (JP) 2010-045461

(51) Int. Cl. H01L 31/05

(52) U.S. Cl. 136/244

(57) ABSTRACT

The solar cell module and the solar cell device have excellent insulation properties, reduced fluctuation of leakage current and high withstand voltage. The solar cell module includes a metal substrate having a metal base and an insulation layer formed on at least one side of the metal base, and a semiconductor circuit provided on the metal substrate. The metal base is connected to a predetermined part of an electric path having a first potential between a minimum potential and a maximum potential of the semiconductor circuit, and a potential of the metal base is maintained at the first potential of the part of the electric path of the semiconductor circuit during the operation of the semiconductor circuit.

### BACKGROUND OF THE INVENTION

The present invention relates to a solar cell module and a solar cell device using the solar cell module provided with a semiconductor circuit on a metal substrate with an insulation layer as an insulation layer of insulation film such as anodized film on a metal base such as an aluminum (Al) base.

There is currently intensive research being conducted on solar batteries in an effort to make improvements from various viewpoints. A solar battery comprises a number of solar cells connected in series on a substrate to form a semiconductor circuit, each of which solar cells is essentially composed of a laminate-structured semiconductor photoelectric conversion layer sandwiched by a lower electrode (back electrode) and an upper electrode (transparent electrode) for generating current by light absorption.

Up to now, glass substrates are mainly used for solar cells, but use of flexible metal substrates is under investigation. There is a possibility that solar cells using metal substrates can be applied to a wide variety of applications compared to ordinary ones using glass substrates, based on characteristics such as the light weight and flexibility of the substrates. Since metal substrates can withstand high-temperature processes, they promise higher efficiency for solar cells together with improved photoelectric conversion properties. However, since solar cells have a semiconductor circuit for performing photoelectric conversion provided on the substrate, an insulation layer is required between the substrate and the semiconductor circuit formed thereon when a metal substrate is used.

For example, there are known methods for forming an insulation layer by covering the substrate with oxides of Si and Al by means of a liquid-phase technique such as a sol-gel method, or a vapor-phase technique such as CVD (chemical vapor deposition) when an iron material such as stainless steel is used as the substrate. However, such techniques generally tend to produce pinholes and cracks, and have essential problems in consistently preparing a large-area insulation layer.

When aluminum (Al) is used as a metal substrate, it is possible to produce an insulation film that has excellent adhesion by forming an anodized film on the surface of the Al base. However, although an anodized film has excellent adhesion, it lacks sufficient insulation properties and there is room for improvement as an insulation layer for solar cells and the like.

The semiconductor circuit described above must withstand voltages that are more than 4 times the maximum voltage of the photovoltaic system, that is, it sometimes requires a withstand voltage of several kilovolts or greater, between the metallic outer frame and the module that is grounded to the ground potential of the power system. A large withstand voltage is needed for the sealing material used between the metallic outer frame of the semiconductor circuit and the module, and the price of such material is rising. When the metal part of the metal substrate of the solar cell is electrically fixed and the module is grounded to the metallic outer frame, the anodized film similarly must also have a withstand voltage of several kilovolts or greater. A high resistance value is also important since the leakage current of the insulation layer is also a prime factor in reduced sun light-to-electric power conversion efficiency of the solar cell module. However, the insulation properties of anodized film are generally not that high.

Note that there are a number of known examples of anodized films formed on the surface of an Al base that have improved insulation properties, and reported methods that include forming an insulation layer on an anodized film (JP 07-147416 A), regulating the intermetallic compounds in the anodized film (JP 2002-241992 A), and increasing the thickness of the barrier layer (the thin layer of dense oxide present near the boundary between the Al and the anodized film) by means of a pore-filling technique (JP 2003-330249 A and H. Takahashi, et al, The Journal of the Metal Finishing Society of Japan, No. 27, 1976, p. 338-343).

JP 2002-359386 A discloses a solar cell string that includes a plurality of solar cells connected in series and/or in parallel with one positive electrode terminal and one negative electrode terminal, wherein the electrical circuit of the solar cell string is grounded at the electrical midpoint of the negative electrode terminal or at one location on the negative electrode terminal side thereof (preferably 2:1) such that at least a part of the electrical circuit of the solar cell string is not housed within an insulation envelope. Since current leaks more easily from the negative electrode side than the positive electrode side in the human body for the voltage to ground, the solar cell disclosed in JP 2002-359386 A is more stable and less likely to get electric shock by placing the ground between the intermediate point (electrical midpoint) and the negative electrode terminal, as described above.

JP 2009-99973 A discloses a solar cell that has a photoelectric conversion layer, which includes a semiconductor layer configured by group Ib elements, group IIIb elements, and group VIb elements, formed on an aluminum substrate provided with an insulating anodized film. This solar cell is a light-weight, inexpensive, and flexible solar cell.

### SUMMARY OF THE INVENTION

The insulation performance of the insulation layer includes a withstand voltage and leakage current (leak), and a higher withstand voltage and lower leakage current are preferred. Although insulation performance is improved by the conventional art disclosed in JP 07-147416 A, JP 2002-241992 A, JP 2003-330249 A, and The Journal of the Metal Finishing Society of Japan, No. 27, 1976, p. 338-343 mentioned above, these methods generally increase the insulation properties of the anodized film which is unrelated to the solar cell. In addition to the conventional art, new methods capable of increasing the insulation properties of the anodized film of the Al substrate of the solar cell are particularly desirable. A low withstand voltage required between the power circuit and the metallic frame of the module is also preferred.

In JP 2002-359386 A, there is a problem of limited use from a safety standpoint since insulation material is not used on the outside of the power generation circuit.

Solar cell modules with a power generation layer provided on a flexible metal substrate sandwiching a thin insulation layer therebetween can be manufactured inexpensively and with excellent production properties, as in the conventional art of JP 2009-99973 A. However, the layer thickness must be increased to increase withstand voltage of the insulation layer in order to obtain satisfactory insulation properties, and the thicker layer causes a problem in adversely affecting production properties and increasing manufacturing costs, thus making implementation difficult.

In response to these needs, an object of the present invention is to eliminate the problems of the conventional art by providing a solar cell module that realizes excellent insulation properties, reduces the high withstand voltage and reduces leakage current fluctuation without implementing the prior art in a solar cell module using a metal substrate with an insulation layer in which an insulation film such as an anodized film is formed on a metal base such as an Al base.

To achieve these objects, the present inventors fabricated a semiconductor circuit for a module configured to have 100 or more solar cells connected in series on the same substrate, the power generation voltage of each of the individual solar cells being at approximately 0.65 V, even when the maximum voltage of the photovoltaic generation device or system is equal to the maximum voltage per module. In consideration of safety and long-term reliability, the insulation layer on the metal substrate requires a withstand voltage of 500 V or greater. When using an insulated substrate or a module with a string-structure and using with a connection in series, a voltage that is n-times the power generation voltage of the respective submodule is generated between the metal on the outside of the module and the submodule containing the semiconductor circuit. It was discovered that, as the number of modules connected in series increases, so increases the voltage generated between the submodule and the metal on the outside of the module such that a higher withstand voltage is required in the insulation layer covering the submodule, and the upper limit of the voltage applied to the insulation layer is reduced by grounding the metal part of the substrate with an insulation layer with the power generation circuit, making the substrate usable as a solar cell substrate despite the thin insulation layer and, hence, resulting in the present invention.

That is, the present inventors noticed that there had been no discussion of the insulation properties when using a metal substrate with an insulation layer, although there had been discussion that grounding the circuit of the solar cell string or solar cell array reduces the voltage-to-ground of the power generation voltage and reduces the withstand voltage required in the insulation material between the power generation layer and the metallic outer frame of the module.

The present inventors also noticed the following points.

In JP 2002-359383 A and JP 2004-146435 A, a steel plate, such as a stainless steel plate, a galvanized steel plate or the like, is provided on the back surface to increase the module strength. Usually, the voltage generated between the steel plate and the substrate is lowest with a negative voltage in the power generation circuit and highest with a positive voltage when a metal substrate is used because the terminal is grounded on the negative side.

The module can be made less expensively by reducing the insulation material between the metallic frame of the module and the power generation circuit of the solar cell with the metal substrate fixed at low potential.

Furthermore, the insulation properties can be improved by providing an insulation layer between the submodule and the module frame, as described in JP 08-83911 A, JP 3520425 B, and JP 11-54780 A by ensuring the insulation properties during modularization.

That is, the solar cell module of the present invention is a solar cell module provided with a semiconductor circuit on a metal substrate with an insulation layer in which an insulation film is formed on at least one side of a metal base, wherein the metal base is connected to a predetermined part of an electric path having a first potential between the minimum potential and the maximum potential of the semiconductor circuit, and the potential of the metal base is maintained at the potential of the part of the electric path of the semiconductor circuit when the semiconductor circuit is operating.

It is preferred that the semiconductor circuit is connected in series and/or parallel.

In the present invention, “semiconductor circuit” means an electronic circuit including a semiconductor provided with the power generation function of a solar cell, and two electrodes sandwiching the semiconductor therebetween.

When the minimum potential side of the semiconductor circuit is connected to the ground side of the solar cell device configured by one or more solar cell modules, it is preferred that the metal base within the solar cell module is connected to a part of the semiconductor circuit with a potential that is lower than the average potential of the semiconductor circuit.

It is also preferred that the metal base is shorted to the part of the semiconductor circuit that has the lowest potential when the semiconductor circuit is operating.

When the metal base within the solar cell module in which the maximum potential side of the semiconductor circuit is connected to the ground side of the solar cell device configured by one or more solar cell modules, it is preferred that the metal base within the solar cell module is connected to a part of the semiconductor circuit with a potential that is higher than the average potential of the semiconductor circuit.

It is also preferred that the metal base is shorted to a part of the semiconductor circuit that has the highest potential when the semiconductor circuit is operating.

In order to fix the potential of the metal substrate, it is permissible to connect the metal substrate through two or more points having different potentials within the solar cell module via electrical resistance, and then set and fix the potential of the metal substrate from the partial potential ratio of the electrical resistance. Since the electrical resistance consumes the power of the solar cell, it is preferable to use a resistance sufficiently high to the degree that minimizes the power consumed by the resistance so as to be negligible.

In the present invention, “average potential of the semiconductor circuit” is intended to mean the intermediate value of the maximum voltages specified by the design of the semiconductor device, for example, when a plurality of photoelectric conversion elements (solar cells), which have the same specifications to generate a current when exposed to sunlight, are connected in series to form an electronic circuit, it is equivalent to the potential at the intermediate point of this electronic circuit. For example, when the total output voltage of a plurality of solar cells connected in series is 100 V, the average potential of the circuit is equivalent to 50 V.

The “connection” referred to in “connection to a part of the semiconductor circuit with a potential that is lower, or a part of that is higher, than the average potential of the semiconductor circuit” includes indirectly connecting a metal base such as an Al base to a part of the circuit through electrical resistance or a separate battery but is not limited to, for example, directly shorting to the electrode. Essentially, any connection configuration may be used insofar as the potential of the metal base is increased to provide a polarity of the electric field such that the metal base is positive at the insulating anodized film formed between the metal base and the semiconductor.

In the present invention, “a part that has the lowest potential” and “a part that has the highest potential” refer to the part of negative and positive maximum voltage respectively according to the design specifications of the semiconductor device. In the case of a solar cell, for example, this part corresponds to the negative electrode of the cell at the end on the most negative side, or the positive electrode of the cell at the end on the most positive side, among the plurality of solar cells connected in series.

Note that the metal base is more preferable to be shorted at the part of the lowest potential or at the part of the highest potential during operation is because the electric field can be reduced between the frame and the power generation circuit.

The metal substrate is configured by an aluminum plate, a stainless steel plate or a steel plate, or an alloy plate or a clad plate incorporating these metals. It is preferable that the metal base is a substrate configured by any one of aluminum, silicon, titanium, and iron, and the insulation layer is configured by an oxide film, a nitride film, or an oxynitride film composed of any one of aluminum, silicon, titanium, and iron. In this case, the withstand voltage required by the insulation layer can be reduced.

It is preferred that the metal base is configured by an aluminum base, and the insulation layer is configured by an anodized film formed on at least one surface of the aluminum base.

The metal substrate is also preferably an aluminum clad material.

The semiconductor of the semiconductor circuit is preferably a photoelectric conversion semiconductor that generates an electrical current by light absorption.

The main component of the photoelectric conversion semiconductor is preferably at least one kind of compound semiconductor with a chalcopyrite structure.

The main component of the photoelectric conversion semiconductor also is preferably at least one kind of compound semiconductor composed of a group Ib element, a group IIIb element, and a group VIb element.

The main component of the photoelectric semiconductor is preferably at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te.

The device configured by the photoelectric conversion semiconductor is not limited to semiconductors of chalcopyrite structure of groups I, III, and VI elements, and preferably has any one of a CIS-CIGS based thin-film solar cell, thin-film silicon based thin-film solar cell, CdTe based thin-film solar cell, group III-V based thin-film solar cell, dye-sensitized thin-film solar cell, and organic thin-film solar cell. In the case of any of these thin-film solar cells, the withstand voltage required by the insulation layer can be similarly reduced.

The solar cell module further has a metallic outer frame or protective metal plate supporting in an electrically insulated state the metal substrate with an insulation layer provided with the semiconductor circuit, and the metallic outer frame or protective metal plate is preferably connected to the ground of the solar cell device configured by one or more solar cell modules.

Further, the metallic outer frame or protective metal plate preferably supports the metal substrate with an insulation layer provided with the semiconductor circuit through an electrical insulation material.

The solar cell device of the present invention has one or more solar cell modules.

When the solar cell device has a plurality of solar cell modules and the plurality of the solar cell modules are connected in series, the connection portion of two solar cell modules is preferably connected to the ground.

According to the present invention, in a solar cell module provided with a semiconductor circuit on a metal substrate with an insulation layer having an insulation film of anodized film or the like on at least one surface of a metal base such as an aluminum (Al) base, the voltage applied to the anodized film during the operation of the semiconductor circuit can be less than the maximum potential of the power generation system, that is, can be set below the power generation voltage per solar cell module, because the metal base is connected to the potential of a part of the semiconductor circuit.

Furthermore, according to the present invention, the voltage applied between the metal substrate and the outer frame of the module can be reduced, thus reducing the cost of the insulation material of the module sealing material, by setting the potential of the metal substrate at a potential near the ground potential of the power system by the potential within the module. Especially, in the present invention, the voltage applied between the metal substrate and the outer frame of the module can be lowered most by using the potential of the metal substrate connected on the negative side in the case of a module disposed on the positive potential side, and using the potential of the metal substrate connected on the positive side in the case of a module disposed on the negative potential side. Note that this situation is completely identical when a plurality of solar cell modules are connected in series in a single solar cell device, and when a plurality of submodules are connected in series in a single solar cell module.

Furthermore, according to the present invention, the cost of the module can be reduced by dealing with a combination of withstand voltages considering manufacturing costs, because it is possible to adjust the voltage applied between the metal substrate and the outer frame of the module and adjust the voltage applied between the anodized film and the power generation circuit by the ground potential of the metal substrate.

### BRIEF DESCRIPTION OF THE DRAWINGS

FIGS. 1A through 1D are circuit diagrams schematically illustrating an embodiment of the solar cell device of the present invention;

FIG. 2 is a circuit diagram schematically illustrating the embodiment of the solar cell module configuring the solar cell device shown in FIGS. 1A and 1D;

FIG. 3 is a cross-section view schematically illustrating the embodiment of the solar cell module illustrated in FIG. 2;

FIG. 4 is a circuit diagram schematically illustrating the embodiment of the solar cell module configuring the solar cell device shown in FIGS. 1B and 1D;

FIG. 5 is a cross-section view schematically illustrating the embodiment of the solar cell module illustrated in FIG. 4;

FIG. 6 is a circuit diagram schematically illustrating the embodiment of the solar cell module configuring the solar cell device shown in FIG. 1C;

FIG. 7 is a cross-section view schematically illustrating the embodiment of the solar cell module illustrated in FIG. 6;

FIG. 8 is a cross-section view schematically illustrating a second embodiment of the solar cell module illustrated in FIG. 6;

FIG. 9 is a perspective view of a solar cell module in the process of manufacture for explaining an example of a process of manufacturing the solar cell module illustrated in FIG. 7;

FIG. 10 is a flow chart showing an example of a method for manufacturing the solar cell module illustrated in FIG. 7; and

FIGS. 11A and 11B are circuit diagrams schematically illustrating conventional solar cell devices.

### DETAILED DESCRIPTION OF THE INVENTION

The solar cell module and solar cell device according to the present invention will be described in detail based upon the preferred embodiments and referring to the attached drawings.

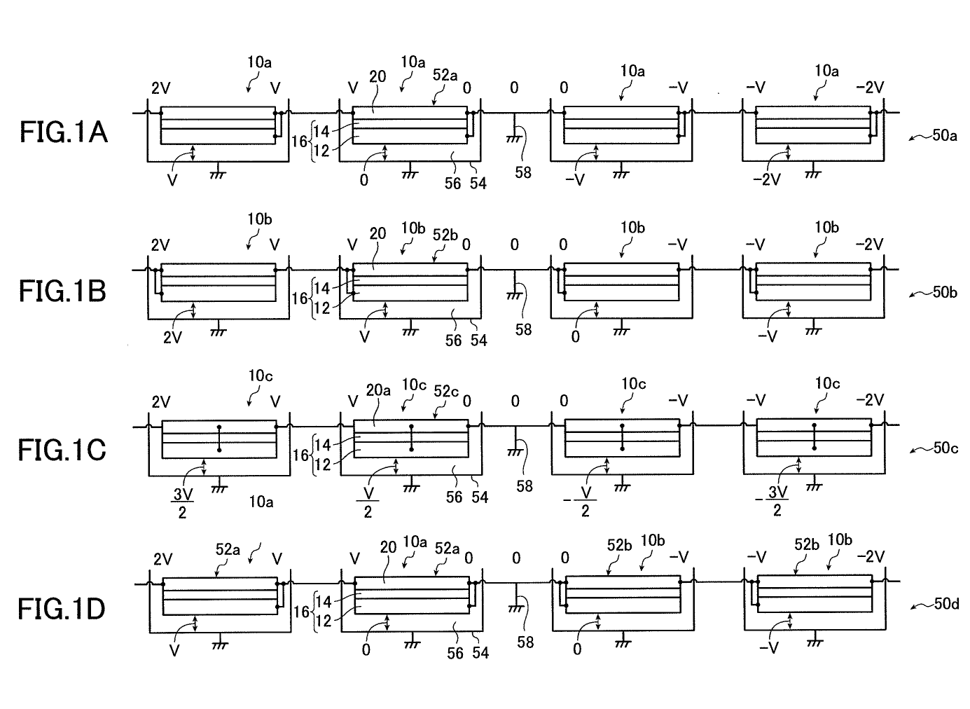

FIGS. 1A through 1D are circuit diagrams respectively schematically illustrating an embodiment of the solar cell device of the present invention. Note that although the representative example of the metal substrate with an insulation layer described below uses a metal substrate with an insulation layer in which an anodized film is formed as an insulation film on at least one surface of an aluminum (Al) base, the present invention is by no means limited to this particular configuration, as shall be described below.

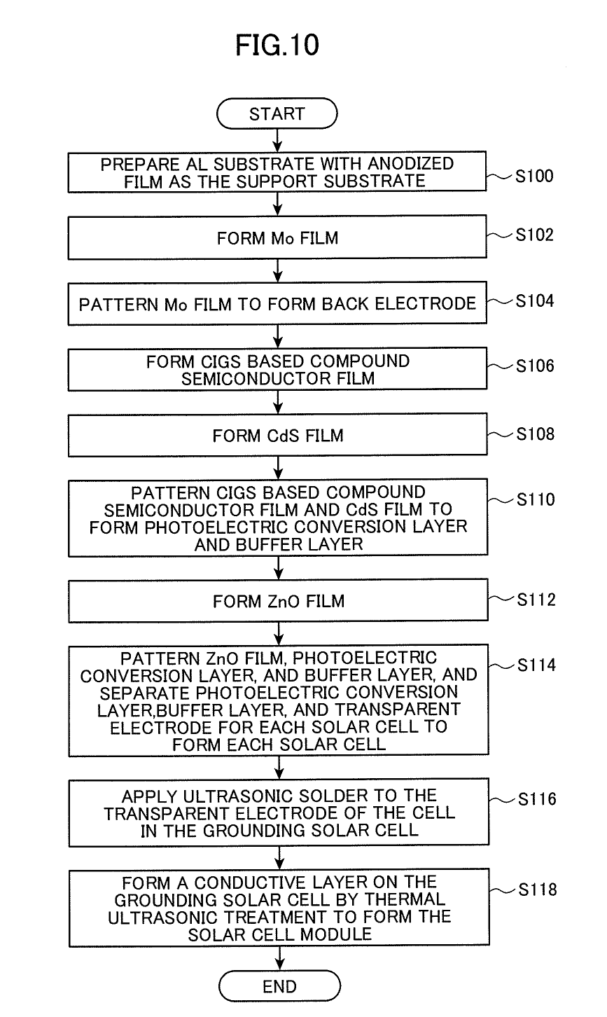

The solar cell device 50a shown in FIG. 1A has four solar cell modules (referred to simply as “modules” below) 10a of the present invention connected in series; the solar cell device 50b shown in FIG. 1B has four solar cell modules 10b of the present invention connected in series; the solar cell device 50c shown in FIG. 10 has four solar cell modules 10c of the present invention connected in series; and the solar cell device 50d shown in FIG. 1D has two solar cell modules 10a and 10b of the present invention respectively connected in series.

Note that in the solar cell devices 50a through 50d, respectively, the solar cell modules configure a solar cell string, the center of which, that is, the center connection portion of the four modules 10a through 10c connected in series, is connected to a ground 58.

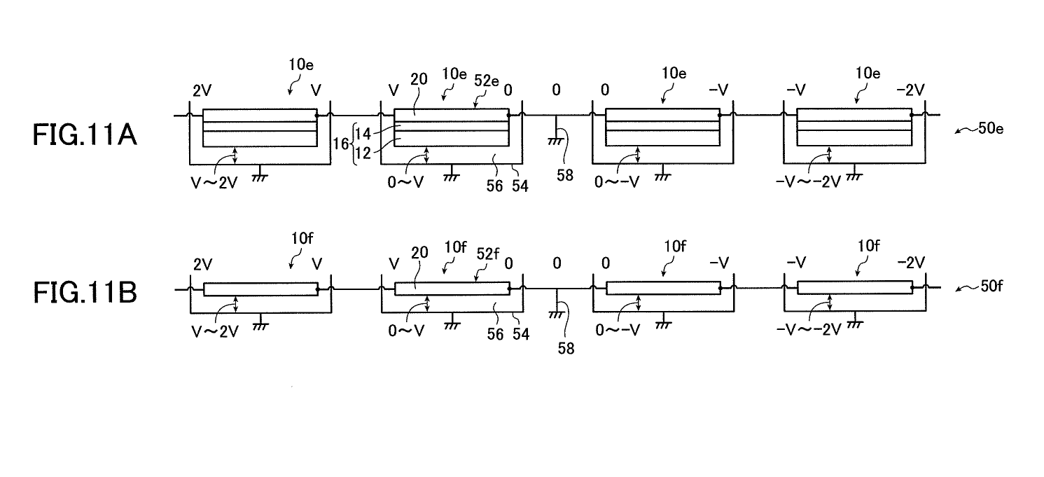

In contrast, FIGS. 11A and 11B are respective circuit diagrams schematically illustrating conventional solar cell devices.

The conventional solar cell device 50e illustrated in FIGS. 11A and 11B are configured by a string of four conventional solar cell modules 10e and 10f respectively connected in series, and similarly, the centers thereof, that is, the center connection portion of the four modules 10e and 10f, are connected to the ground 58.

Although two modules are shown connected in series on both electrode sides in order to simplify the description in FIGS. 1 and 11, it is to be noted that the efficacy of the present invention can be obtained with one, or three or more, modules disposed on both electrode sides. The efficacy of the present invention can also be similarly obtained by a configuration in which each module or module array connected in series have the same modules connected in parallel.

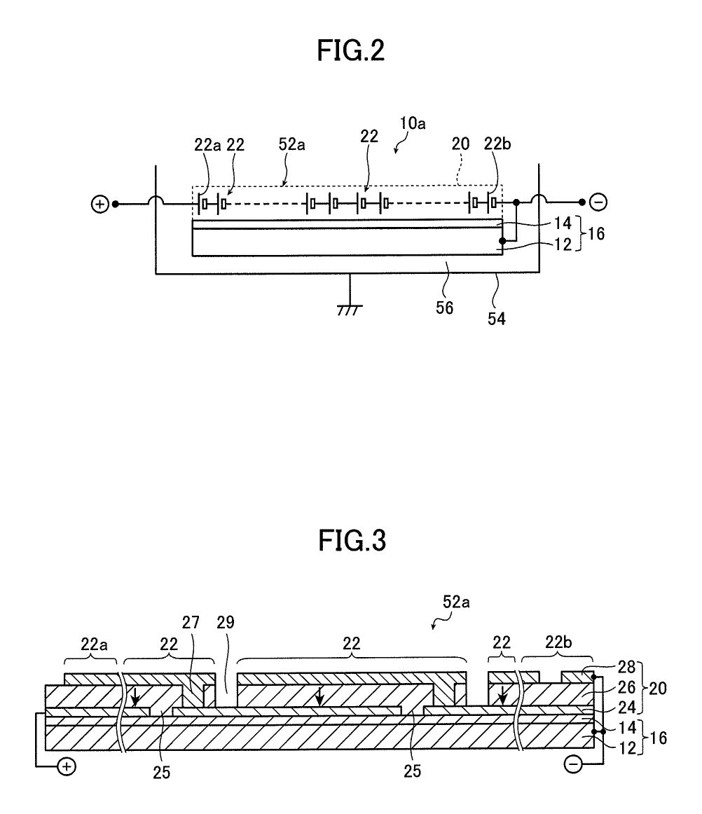

In the solar cell device 50a illustrated in FIG. 1A, each module 10a has, for example as shown in FIG. 2, a metal substrate with an insulation layer (referred to as “support substrate” below) 16 provided with a metal substrate 12 with a grounded substantially rectangular Al base and an electrical insulation layer 14 composed of an anodized film formed on the Al base of the metal substrate 12, a submodule 52a having a power generation layer 20 composed of a plurality of solar cells 22 connected in series and formed on the insulation layer 14 to configure the semiconductor circuit of the present invention, a metallic outer frame (referred to as “back metal plate” or “back protective metal plate” below) 54 composed of an outer frame supporting the module from the back side so that the submodule 52a, including the electrical circuits, is in an electrically insulated state, and an electrical insulation member 56 for maintaining the submodule 52a and the metallic outer frame in an electrically insulated state.

The module 10a has a positive (plus) side at the solar cell 22a as a positive terminal disposed at one end among a plurality of solar cells 22 of the power generation layer 20, and has a negative (minus) side at the solar cell 22b as a negative terminal disposed at the other end. The Positive terminal, for example, is connected to the negative terminal (refer to FIG. 1A) of the adjacent module 10a via a ribbon-shaped lead wire, or to the positive terminal of a connection box not shown in the drawing, and the negative terminal, for example, is connected to the positive terminal (refer to FIG. 1A) of the adjacent module 10a via a ribbon-shaped lead wire, or to the negative terminal of a connection box not shown in the drawing. In each module 10a, the metallic outer frame 54 is connected to the ground (grounded).

The solar cell device 50a of the present invention has four modules 10a, in all of which the circuit (minus (−) electrode of the power generation layer 20) of the submodule 52a and the Al base material of the metal substrate 12 on the right side in FIG. 1A, that is, on the side of lowest potential (low potential side) within each module 10a, is connected to the negative terminal of the solar cell 22b of the power generation layer 20 shown in FIG. 2. Note that details of the submodule 52a and the power generation layer 20 will be described later using FIG. 3.

Below, the electrical connection of the metal substrate 12 refers to the electrical connection of the Al base of the metal substrate 12.

Accordingly, as shown in FIG. 1A, when the drive voltage of each module 10a of the solar cell device 50a is V, the total drive potential of the solar cell device 50a is 4 V; however, when the ground 58 at the center is 0, the potential of the terminals on both sides of each module 10a is 2 V and V, V and 0, 0 and −V, −V and −2V, counting from the left module 10a in the drawing.

Hence, in each module 10a in the solar cell device 50a, the potential of the metal substrate 12 of each module 10a during operation becomes the low potential of the module 10a, that is, V, 0, −V, and −2V counting from the left in the drawing, because the circuit of the submodule 52a and the metal substrate 12 are connected on the low potential side. Therefore, in the solar cell device 50a, the voltage (potential difference of the insulation film) acting on the insulation layer 14 is a maximum value of V in any submodule 52a, and the voltage between the metal substrate 12 and the metallic outer frame 54 is V, 0, −V, and −2V counting from the module 10a on the left in the drawing because the metallic outer frame 54 is disposed at the ground 58, and thus, the maximum value (absolute value) is 2 V.

Note that the electrical field between the power generation layer 20 and the metallic outer frame 54 can be reduced since the Al base of the metal substrate 12 is shorted to the part of lowest potential of the power generation layer 20 during operation as in the present embodiment. In particular, the electric field can be made smaller in the module 10a on the higher potential side than the ground 58, that is, on the positive electrode side.

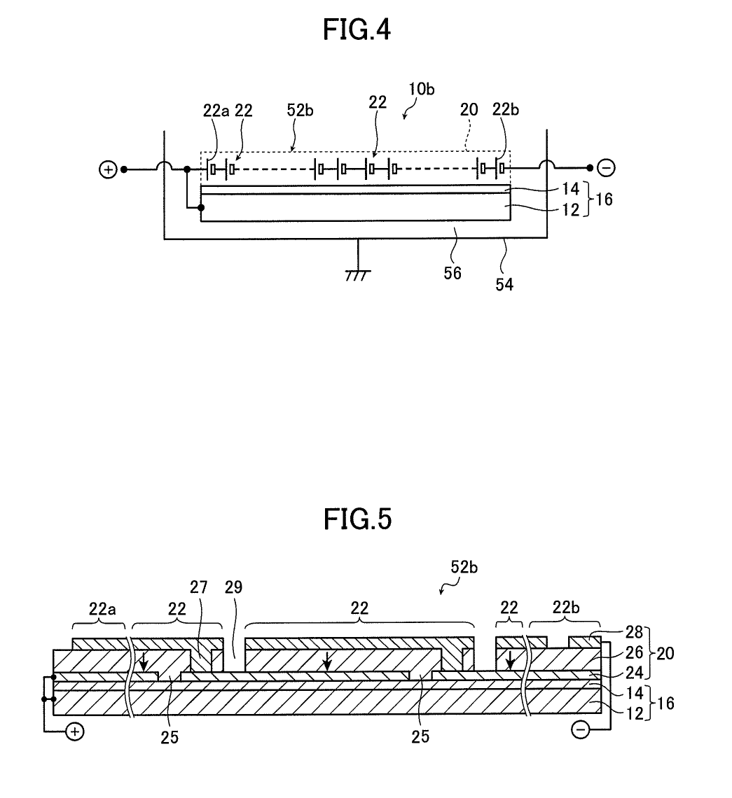

The modules 10b of the solar cell device 50b shown in FIG. 1B, as in FIG. 4, have a submodule 52b, metallic outer frame 54, and an electrical insulation member 56, and the submodule 52b has a metal substrate 12, insulation layer 14, and a power generation layer 20. Detailed description is abbreviated since the structure is identical to the module 10a shown in FIG. 1A and FIG. 2 with the exception of the circuit of the metal substrate 12 and the submodule 52b, that is, the connection of the positive electrode of the solar cell 22a of the power generation layer 20. Note that details of the submodule 52b will be described later using FIG. 5.

The solar cell device 50b has four modules 10b, in all of which the circuit (plus (+) electrode of the power generation layer 20) of the submodule 52b and the metal substrate 12 on the left side in FIG. 1B, that is, on the side of highest potential (high potential side) within the module 10b, is connected to the positive terminal of the solar cell 22a of the power generation layer 20 of the submodule 52b shown in FIG. 4.

Accordingly, as shown in FIG. 1B, when the drive voltage of each module 10b of the solar cell device 50b is V, the total drive potential of the solar cell device 50b is 4 V; however, when the middle ground 58 is 0, the potential of the terminals on both sides of each module 10b is 2 V and V, V and 0, 0 and −V, −V and −2V, counting from the left module 10a in the drawing, similar to FIG. 1A.

Hence, in each module 10b in the solar cell device 50b, the potential of the metal substrate 12 of each module 10b during operation becomes the high potential of the module 10b, that is, 2V, V, 0, −V counting from the module 10b on left in the drawing, because the circuit of the submodule 52b and the metal substrate 12 are connected on the high potential side. Therefore, in the solar cell device 50b, the voltage acting on the insulation layer 14 is a maximum value of V in any module 10b, and the voltage between the metal substrate 12 and the metallic outer frame 54 is 2V, V, 0, and −V counting from the module 10a on the left in the drawing because the metallic outer frame 54 is disposed at the ground 58, and thus, the maximum value is 2 V.

Note that the electrical field between the power generation layer 20 and the metallic outer frame 54 can be reduced since the Al base of the metal substrate 12 is shorted to the part of highest potential of the power generation layer 20 during operation as in the present embodiment. In particular, the electric field can be made smaller in the module 10b on the lower potential side from the ground 58, that is, on the negative electrode side.

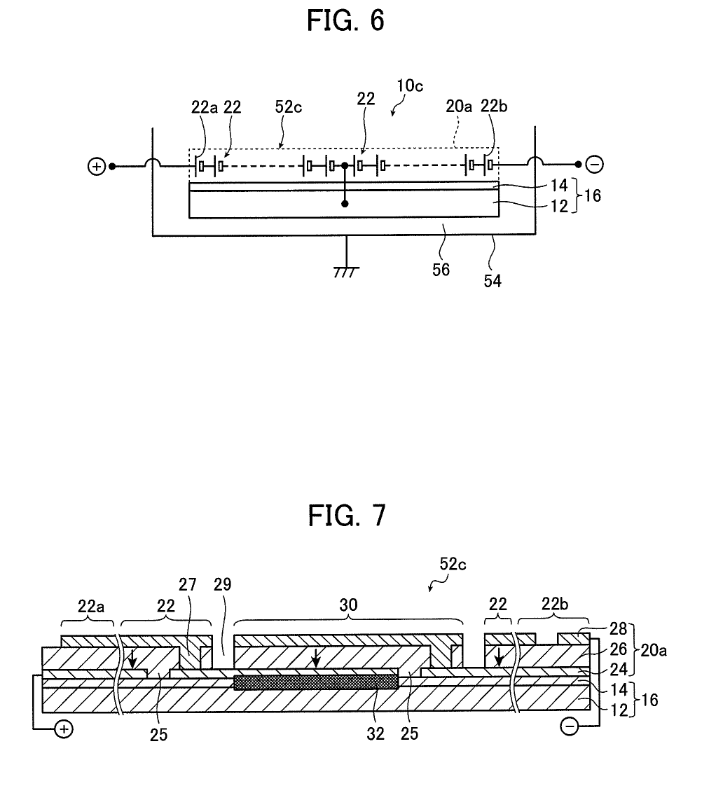

The modules 10c of the solar cell device 50c shown in FIG. 1C, as shown in FIG. 6, have a submodule 52c, a metallic outer frame 54, and an electrical insulation member 56, and the submodule 52c has a metal substrate 12, an insulation layer 14, and a power generation layer 20a. Detailed description is abbreviated since the structure is identical to the module 10a of the solar cell device 50a shown in FIG. 1A and FIG. 2 with the exception of the configuration of the power generation layer 20a and the connection of the circuit of the metal substrate 12 and the submodule 52c, that is, the connection of the power generation layer 20a (the connection of the grounding solar cell 30 (refer to FIG. 7) to the electrode of the solar cell 22 at the center or near the center of the plurality of solar cells 22. Note that details of the submodule 52c and the power generation layer 20a will be described later.

The solar cell device 50c, in all of the four modules 10c, is connected to the metal substrate 12 and the circuit of the submodule 52a (electrode at the center of the power generation layer 20) at the average potential of the power generation layer 20a of each module 10c, that is at the center side (midpoint potential side) that has a potential near the average potential within the power generation layer 20a. That is, the solar cell device 50c is directly connected electronically to the Al substrate of the metal substrate 12 of the support substrate 16 using either the positive side or negative side of the two solar cells 22 at the center of the plurality of solar cells 22, or the solar cells 22 substantially at the center, as a connection terminal.

Accordingly, as shown in FIG. 10, when the drive voltage of each module 10c of the solar cell device 50c is V, the total drive potential of the solar cell device 50c is 4 V; however, when the middle ground 58 is 0, the potential of the terminals on both sides of each module 10c is 2 V and V, V and 0, 0 and −V, −V and −2V, counting from the left module 10c in the drawing, similar to FIG. 1A.

Hence, in each module 10c in the solar cell device 50c, the potential of the metal substrate 12 of each module 10c during operation becomes the average potential of the module 10c, that is, 3V/2, V/2, −V/2, and −3V/2 counting from the module 10c on left in the drawing, because the circuit of the submodule 52b and the metal substrate 12 are connected on the midpoint potential (average potential) side. Therefore, in the solar cell device 50c, the voltage acting on the insulation layer 14 is a maximum value of V/2 in any module 10c, and the voltage between the metal substrate 12 and the metallic outer frame 54 is 3V/2, V/2, −V/2, and −3V/2 counting from the module 10c on the left in the drawing because the metallic outer frame 54 is disposed at the ground 58, and thus, the maximum value is 3V/2.

In the present invention, “average potential” of the power generation layer 20a is intended to mean the intermediate value or approximate intermediate value of the maximum potential specified by the design of the power generation layer 20a. As shown in FIG. 6, for example, the potential of the solar cell 22 at the intermediate point or approximate intermediate point of the power generation layer 20a connected in series to a plurality of solar cells 22 is equal to the potential of the grounding solar cell 30 shown in FIG. 7.

Although, in the submodule 52c of the present invention, the positive electrode or negative electrode of the grounding solar cell 30 is directly connected to the metal substrate 12 of the support substrate 16, it is most preferred that the grounding solar cell 30 is the solar cell 22 at the center position or approximate center position of the plurality of solar cells 22, as shown in FIGS. 6 and 7.

This ensures that the number of solar cells 22 located on one side of the center of the solar cells through the solar cell 22a at one end, i.e., the number of solar cells 22 in the power generation layer 20a on the plus (positive) side agree or substantially agree with the number of solar cells 22 through the solar cell 22b at the other end, i.e., the number of solar cells 22 in the power generation layer 20b on the minus (negative) side. Thus, the number of solar cells 22 can be halved as compared with the number of solar cells 22 in the power generation layer 20 of the submodule 52a and 52b shown in FIGS. 2 and 4, and the submodule 52e in the conventional module 10e shown in FIG. 1E, i.e., the number of solar cells 22 located between the solar cells 22a and 22b at both ends, where the grounding solar cell 30 is not provided. As a result, the voltage acting on the insulation layer 14 has a maximum value of V/2, which is half.

As a result, in the power generation layer 20a of the submodule 52c of the illustrated example, the potential of the metal substrate 12, that is, the magnitude of the potential difference (voltage) between the ground potential of the grounding solar cell 30 and the positive potential at the positive terminal of the solar cell 22a at the left end in the drawing and the magnitude of the potential difference (voltage) between the ground potential of the grounding solar cell 30 and the negative potential at the negative terminal of the solar cell 22b at the right end in the drawing can be equalized or substantially equalized, and can be halved as compared with the potential difference (voltage) between the solar cells 22a and 22b in the power generation layer 20 of the other submodules 52a and 52b, and the conventional submodule 52e.

Therefore, with the solar cell module 10c where the voltage between the metal substrate 12 and the power generation layer 20a is half of that between the metal substrate 12 and the power generation layer 20a in the other modules 50a, 50b, and 50e, the withstand voltage required of the insulation layer 14 between the metal substrate 12 and the power generation layer 20a may be half of that required in the case of the other modules 50a, 50b, and 50e, and hence, where an insulation layer 14 having the same withstand voltage is used, the potential difference (voltage) in the whole power generation layer 20a, i.e., between the solar cells 22a and 22b, can be doubled, permitting fabrication of a solar cell module having a doubled voltage.

Note that although the solar cell module 10c illustrated in FIG. 6 is grounded at the position connected to the metal substrate 12 (the position of the grounding solar cell 30) at the center or at substantially the center of the plurality of arrayed solar cells 22 (at the solar cell 22 located in that position), the present invention is not limited to that configuration; grounding may be established through a solar cell 22 located in a range of plus or minus 10% from the center, i.e., in a range from plus 10% to minus 10% from the center of the arrayed solar cells 22, the solar cell 22a at one end and the solar cell 22b ac the other end being located at + (plus) 100% to − (minus) 100% from the center, respectively.

This is because, similar to the above case, the withstand voltage required in the insulation layer 14 can be reduced compared to the other modules even when the grounded position in the module 10c is the solar cell 22 disposed within a range of plus or minus 10% from the center solar cell 22; when using insulation layers 14 of the same withstand voltage, the total voltage of the power generation layer 20a can be increased to produce a module that generates a high voltage.

For the reasons stated above, it is of course more preferable according to the present invention to establish grounding through a solar cell 22 located in a range of plus or minus 5% from the center, or in a range of + (plus) 5% to − (minus) 5% from the center.

The solar cell device 50d illustrated in FIG. 1D disposes two modules 10a of the solar cell device 50a shown in FIG. 1A on the positive (high) potential side at the left side of FIG. 1D, and disposes two modules 10b of the solar cell device 50b shown in FIG. 1B on the negative (low) potential side at the right side of FIG. 1D via the ground 58. Accordingly, in the solar cell device 50d, the circuit of the submodule 52a and the metal substrate 12 is connected on the side of lowest potential (negative (−) electrode side of the solar cell 22b of the power generation layer 20) within the two modules 10a on the right side in FIG. 1D, and the circuit of the submodule 52b and the metal substrate 12 is connected on the side of highest potential (positive (+) electrode side of the solar cell 22 of the power generation layer 20) within the two modules 10b on the left side.

Accordingly, as shown in FIG. 1D, when the drive voltage of each module 10a and 10b of the solar cell device 50d is V, the total drive potential of the solar cell device 50b is 4V; however, when the ground 58 at the center is 0, the potential of the terminals on both sides of modules 10a and 10b is 2V and V, V and 0, 0 and −V, −V and −2V, counting sequentially from the left module 10a in the drawing, similar to FIG. 1A.

In the solar cell device 50d, potential of the metal substrate 12 of the two modules 10a during operation is the low potential of the modules 10a shown in the left side in the drawing because the circuit of the submodule 52a and the metal substrate 12 is on the low potential side in the two modules 10a, and the potential of the metal substrate 12 of the two modules 10b during operation is the high potential of the modules 10b on the right side of the drawing because the circuit of the submodule 52b and the metal substrate 12 is on the high potential side in the two modules 10b, that is, V, 0, 0, and −V counting from the module 10a on the left side. Therefore, in the solar cell device 50d, the voltage acting on the insulation layer 14 is a maximum value of V in both modules 10a and 10b, and the voltage between the metal substrate 12 and the metallic outer frame 54 is V, 0, 0, and −V counting sequentially from the module 10a on the left in the drawing because the metallic outer frame 54 is disposed at the ground 58, and thus, the maximum value is V. The solar cell device 50d illustrated in FIG. 1D is therefore highly preferred because the voltage acting on the insulation layer 14 is the same as that of the solar cell devices 50a and 50b shown in FIGS. 1A and 1B, whereas the voltage acting on the insulation layer 14 is higher than that of the solar cell device 50c shown in FIG. 1C, and the voltage between the metallic outer frame 54 and metal substrate 12 is lower than any of that in the solar cell devices 50a through 50c.

Although the circuits of the metal substrate 12 and the power generation layer 20 or 20a of the submodules 52a through 52c are connected to the low potential side of the right end, high potential side of the left end, and average potential of the midpoint potential side in the modules 10a through 10c of the examples mentioned above, the present invention is not particularly limited to these configurations since the circuit of the metal substrate 12 and the power generation layer 20 or 20a also may be connected between the low potential side and the midpoint potential side, or between the high potential side and the midpoint potential side insofar as the potential of the metal substrate 12 during operation is maintained at a predetermined potential of the circuit of the power generation layer 20 or 20a. Note that when the lowest (minimum) potential side of the power generation layer 20 or 20a is connected to the ground 58 side, the metal substrate 12 is preferably connected to the part having a lower than average potential of the modules 10a through 10c, and when the highest (maximum) potential side of the power generation layer 20 or 20a is connected to the ground 58, the metal substrate 12 is preferably connected to the part having higher than average potential of the modules 10a through 10c.

On the other hand, the module 10e of the conventional solar cell device 50e illustrated in FIG. 11A has a submodule 52e, a metallic outer frame 54, and an electrical insulation member 56, and the submodule 52e has a metal substrate 12, an insulation layer 14 and a power generation layer 20. Detailed description is abbreviated since the structure is identical to the module 10a of the solar cell device 50a shown in FIG. 1A with the exception that the circuit of the metal substrate 12 and the submodule 52b is not connected.

The solar cell device 50e has a total of four modules 10e in which the metal substrate 12 is not connected to the circuit of the submodule 52a and is not grounded, and thus has a potentially floating condition.

The module 10f of the conventional solar cell device 50f shown in FIG. 11B uses a submodule 52f that has only a power generation layer 20 without having a metal substrate 12 and its insulation layer 14 rather than using the submodule 52e of the module 10e of the conventional solar cell device 50e shown in FIG. 11A. In this conventional solar device, the back electrodes of the power generation layer are aligned without a metal substrate on the back surface. Therefore, a potential distribution can be formed on the back surface in this conventional solar cell device.

Accordingly, as shown in FIG. 11A, when the drive voltage of each module 10e of the solar cell device 50e is V, the drive potential of the entire solar cell device 50e is 4 V; however, when the ground 58 at the center is 0, the potential of the terminals on both sides of each module 10e is 2V and V, V and 0, 0 and −V, −V and −2V, counting from the left module 10e in the drawing, similar to FIG. 1A.

Since the potential of the metal substrate 12 of the module 10e during operation is a floating state in the solar cell device 50e, the voltage between the metallic outer frame 54 and the power generation layer 20 of the submodule 52e is V to 2V, 0 to V, 0 to −V, and −V to −2V counting from the left module 10e in the drawing for any module 10e in the solar cell device 50e. As a result, there is concern that the voltage acting on the insulation layer 14 and the potential between the metallic outer frame 54 and the metal substrate 12 also have a maximum value of 2V. Since the potential between the metal substrate 12 and the power generation layer 20 of the submodule 52e is in a floating state, this potential may double due to the influence of the accumulated load in the metal substrate when the voltage fluctuates rapidly such as when the solar cell is in shade. Therefore, the maximum potential difference between the metal substrate 12 and the power generation layer 20 of the submodule 52e is 4V, 2V, −2V, and −4V counting from the left module 10e in the drawing.

Note that in the conventional solar cell device 50f illustrated in FIG. 11B the voltage between the metallic outer frame 54 and the power generation layer 20 of the submodule 52f is V to 2V, 0 to V, 0 to −V, and −V to −2V counting from the high voltage side of the four modules 10f.

Based on the above discussion, the conventional solar cell device 50e illustrated in FIG. 1E increases the voltage acting on the insulation layer 14 more than any of the solar cell devices 50a through 50d of the present invention shown in FIGS. 1A through 1D. Note also that although the voltage between the metal outer frame 54 and the metal substrate 12 in the solar cell device 50e and solar cell device 50f is the same as in the solar cell devices 50a and 50b of the present invention, this voltage becomes larger than that in the solar cell devices 50a and 50b of the present invention.

Therefore, the solar cell devices 50a through 50d of the present invention are invariably superior to the conventional solar cell device 50e in regard to the withstand voltage of the insulation layer 14. Both solar cell devices 50c and 50d of the present invention are also superior to the conventional solar cell device 50e and solar cell device 50f in regard to the withstand voltage between metallic outer frame 54 and the metal substrate 12.

The support substrate 16 used in the modules 10a through 10c of the illustrated solar cell devices 50a through 50d is a metal substrate with an insulation layer provided with a metal substrate 12 that has an Al base, and an insulation layer 14 composed of an anodized film layer formed on the Al base. Although the support substrate 16 is not particularly limited insofar as the it is a metal substrate with an insulation layer provided with an Al base on which an anodized film is formed as an insulation layer, it is preferred that the support substrate 16 is a support substrate configured by a metal substrate 12 provided with an Al plate having an anodized film formed thereon as an insulation layer 14 by anodizing at least one surface of the aluminum (Al) plate used as the Al base. Note that when an Al base is used as the support substrate 16, the anodized film formed by anodizing the surface of the Al base becomes the insulation layer 14, and the Al base that is not anodized becomes the metal substrate 12.

In the present invention, “Al base” is intended to mean a metal base having Al as a main component, and more specifically refers to a metal base having an Al content of 90 mass % or more. The Al base may contain trace elements, may be a pure Al base, and may be an alloy base of Al and another metal element. The “main component” of the layer formed on the metal substrate with an insulation layer (back electrode or bottom electrode, photoelectric conversion layer, transparent electrode or top electrode, and other optional layer provided as needed, to be described later) is defined as a component content of 75 mass % or more.

The metal substrate 12 is not specifically limited, provided that it allows the insulation layer 14 to be formed and can support the power generation layers 20 and 20a when formed into the support substrate 16 that is a metal plate with an insulation layer. The metal substrate 12 is preferably a metal substrate at least one side of which is an aluminum base and may be exemplified by an aluminum substrate and a composite aluminum substrate made of aluminum and other metals, that is, a so-called aluminum (Al)-clad material.

The thickness of the metal substrate 12 may be selected as appropriate considering the overall strength required of the modules 10a through 10c and submodules 52a through 52c, and preferably has a thickness in a range of 0.1 to 10 mm when formed as the support substrate 16. When fabricating the support substrate 16 from an aluminum substrate, a composite aluminum substrate or the like, the thickness must allow for reduction in thickness caused by anodization, washing prior to anodization, and grinding.

An aluminum substrate used in the present invention may for example be Class 1000 pure aluminum according to the Japan Industrial Standard (JIS) or an alloy plate formed of aluminum and other metal elements exemplified by an Al—Mn alloy plate, an Al—Mg alloy plate, an Al—Mn—Mg alloy plate, an Al—Zr alloy plate, an Al—Si alloy plate, and an Al—Mg—Si alloy plate.

The composite aluminum substrate may be a clad plate formed of an aluminum plate and a plate of other metals, such as a clad plate formed of an aluminum plate and a stainless steel (SUS) plate, a clad plate formed of a plate of any variety of steels sandwiched by two aluminum plates, and the like. According to the present invention, in addition to various stainless steel plates, other metal plates used with an aluminum plate to form a clad plate may for example be one made of a steel such as mild steel, Invar alloy 42, Kovar alloy, or Invar alloy 36. Alternatively, the metal plate may be one permitting use as a roof material, a wall material, etc. for a residential house or a building to allow the solar cell modules of the present invention to be used as a solar panel of a type that can be integrated with the roof material.

An aluminum plate, an aluminum alloy plate, etc. used for that purpose may contain a trace amount of a metal element such as Fe, Si, Mn, Cu, Mg, Cr, Zn, Bi, Ni, and Ti.

The insulation layer 14 formed on the metal substrate 12 is an anodized film formed on the surface by anodizing the Al substrate or composite aluminum substrate. Anodization of an aluminum substrate or a composite aluminum substrate may be achieved by immersing the aluminum substrate or the composite aluminum substrate, acting as a positive electrode, together with a negative electrode in an electrolytic solution and applying a voltage between the positive and negative electrodes to complete electrolytic treatment.

The anodized film to serve as the insulation layer 14 may be formed on one side of the aluminum layer of an aluminum substrate or a composite aluminum substrate constituting the metal substrate 12 as described above. In the case of a clad plate comprising an aluminum substrate or a clad plate formed of a metal plate sandwiched by two aluminum plates, the anodized film is provided preferably on both sides of the aluminum layer to minimize warps and cracks produced in the anodized films caused by a difference in thermal expansion coefficient between the aluminum layer and the anodized film in the process of, for example, fabricating the power generation layer 20.

The thickness of the insulation layer 14 or the anodized film is not specifically limited, provided that the insulation layer 14 has insulation properties and a surface hardness sufficient to prevent, for example, damage that may be caused by a mechanical impact during handling. An excessive thickness thereof, however, may cause problems from the viewpoint of flexibility. Although the thickness of the insulation layer 14 may be 0.5 to 50 micrometers, a thickness of 20 micrometers or less is preferable because the present invention can reduce the withstand voltage of the insulation layer 14. Note that control of the thickness of the insulation layer 14 can be accomplished by controlling the electrolysis time as well as the conditions of galvanostatic electrolysis and potentiostatic electrolysis.

The metallic outer frame 54 used in the modules 10a through 10c and 10e of the present invention may be various insofar as the submodules 52a through 52c can be supported from the back side, and the known metallic outer frame, protective metal plate, back metal plate, back metal member and the like used in the conventional solar cell modules may be so employed. A steel material, an aluminum, or an aluminum alloy material is used as the metallic outer frame. An aluminum/aluminum alloy plate, a copper plate, a galvanic steel plate and the like may be used as the back metal plate.

The electrical insulation member 56 used in the modules 10a through 10c, and 10e of the present invention may be various insofar as the submodules 52a through 52c and the metallic outer frame 54 are maintained in an electrically insulated state while the metallic outer frame 54 supports the back side of the submodules 52a through 52c, and the known insulating resin materials for use in solar cell modules may be so employed. Examples of insulating resin materials include EVA (ethylene vinyl acetate), PET (polyethylene terephthalate), PVF (polyvinyl fluoride), and PVB (polyvinyl butyral).

The submodules 52a through 52c of the modules 10a through 10c of the present invention illustrated in FIGS. 3, 5, and 7 are called substrate type submodules, and the power generation layers (photoelectric conversion element) 20 and 20a provided on the submodules 52a through 52c are integrated thin film type layers. The power generation layer 20 provided on the submodules 52a and 52b has a plurality of solar cells 22 connected in series and formed on the insulation layer 14 of the support substrate 16, and the power generation layer 20a provided on the submodule 52c has a plurality of solar cells 22 connected in series and formed on both sides of the grounding solar cell 30 disposed in the center or substantially the center on the insulation layer 14 of the support substrate 16, and differs from the power generation layer 20 in having a grounding solar cell 30.

The plurality of solar cells 22 common to the power generation layers 20 and 20a are described below, and the grounding solar cell 30 provided on the power generation layer 20a is described in succession.

The solar cells 22 have the back electrode 24 formed on the surface of the insulation layer 14 of the support substrate 16, the photoelectric conversion layer 26 formed on the back electrode 24 so as to electrically convert the received light, and the transparent electrode 28 formed on the photoelectric conversion layer 26, wherein the back electrode 24, the photoelectric conversion layer 26, and the transparent electrode 28 are laminated sequentially on the insulation layer 14.

On the other hand, the grounding solar cell 30 comprises a conductive layer 32 that is a part of the insulation layer 14 formed on the support substrate 16 of the solar cells 22 so that, as in the case of the solar cells 22, the back electrode 24, the photoelectric conversion layer 26, and the transparent electrode 28 are laminated sequentially on the conductive layer 32. The grounding solar cell 30 may or may not contribute to power generation, provided that the conductive layer 32 is formed to permit electric conduction between the back electrode 24 and the metal substrate 12.

Although not shown in FIGS. 3, 5, and 7, the solar cells 22 and the grounding solar cell 30 may comprise a buffer layer on the photoelectric conversion layer 26 so that the back electrode 24, the photoelectric conversion layer 26, the buffer layer, and the transparent electrode 28 are laminated sequentially.

In the plurality of solar cells 22, the back electrodes 24 are formed on the surface of the insulation layer 14 so that each of them extends from a region on an end side (a part thereof on the right side in the drawing) of an adjacent (located on the left side thereof in the drawing) solar cell 22 (or the grounding solar cell 30; refer to FIG. 7) and through a majority of a region of the solar cell 22 of interest (left side in the drawing), with a predetermined gap 25 from the back electrode 24 of the adjacent solar cell 22, as shown in FIGS. 3, 5, and 7.

In also the grounding solar cell 30 as in the solar cells 22, the back electrode 24 is formed on the surface of the conductive layer 32 and the insulation layer 14 so that it extends from a region on an end side (a part thereof on the right side in the drawing) of the adjacent solar cell 22 (on the left side in the drawing) and through a majority of a region of the grounding solar cell 30 (on the left side in the drawing), with a predetermined gap 25 from the back electrode 24 of the adjacent solar cell 22. The major part of the back electrode 24 of the grounding solar cell 30 is located on the conductive layer 32.

The photoelectric conversion layers 26 of the plurality of solar cells (referred to simply as battery cells below) 22 and the grounding solar cell (referred to simply as battery cell below) 30 are formed on the back electrodes 24 so as to fill the gap 25 between the adjacent back electrodes 24. Therefore, the photoelectric conversion layers 26 are in direct contact with the insulation layers 14 and/or conductive layer 32 at this gap 25.

Each photoelectric conversion layer 26 has a groove 27 extending from an adjacent battery cell 22 or 30 and reaching the back electrode 24. Thus, each groove 27 is formed at a different position (right side in the drawing) than the gap 25 located between adjacent back electrodes 24.

The transparent electrodes 28 are formed on the surface of the photoelectric conversion layers 26 in such a manner as to fill the grooves 27 of the photoelectric conversion layers 26. Accordingly, each transparent electrode 28 is in direct contact and therefore electrically connected with the back electrode 24 of an adjacent battery cell 22 or 30 at this groove 27. Thus, the two adjacent battery cells 22 and adjacent battery cells 22 and 30 are connected in series.

Further, in the plurality of the battery cells 22 and 30, an opening 29 reaching to the back electrode 24 is formed between the transparent electrode 28 and the photoelectric conversion layer 26 of the battery cells 22 or 30 on the one hand and between the transparent electrode 28 and the photoelectric conversion layer 26 of the adjacent battery cells 22 or 30 on the other hand. Thus, the two adjacent battery cells 22 and the adjacent battery cells 22 and 30 are separated from each other, respectively by the opening 29.

As described above, serial connection of the plurality of battery cells 22 and 30 is established as the transparent electrode 28 of a battery cell 22 or 30 is connected with the back electrode 24 of its adjacent battery cell 22 or 30.

In the submodule 52a illustrated in FIG. 3, the back electrode 24 of the battery cell 22a at one end (on the left side in the drawing) of the power generation layer 20 has a lead wire in the form of a copper ribbon or the like, not shown, attached thereto to provide a positive (+) terminal, and the transparent electrode 28 of the battery cell 22b at the other end (on the right side in the drawing) of the power generation layer 20 has a similar lead wire attached thereto to provide a negative (−) terminal, both of which are connected (shorted) to the metal substrate 12 (Al base). Note that the connection (short) between the transparent electrode 28 and the metal substrate 12 also may be accomplished by forming a conductive layer to cover the metal substrate 12 and the transparent electrode 28 on the right end of the battery cell 22b, the connection may be accomplished by soldering or the like, and the connection may be accomplished by wiring or the like.

In the submodule 52b illustrated in FIG. 5, the back electrode 24 of the battery cell 22a at one end (on the left side in the drawing) of the power generation layer 20 has a similar lead wire attached thereto to provide a positive (+) terminal, and the transparent electrode 28 of the battery cell 22b at the other end (on the right side in the drawing) of the power generation layer 20 has a similar lead wire attached thereto to provide a negative (−) terminal, both of which are connected (shorted) to the metal substrate 12 (Al base). Note that the connection (short) between the back electrode 24 and the metal substrate 12 also may be accomplished by forming a conductive layer to cover the metal substrate 12 and the back electrode 24 on the left end of the battery cell 22a, the connection may be accomplished by soldering or the like, the connection may be accomplished by wiring or the like, and may be accomplished by breaking the insulation layer 14 between the metal substrate 12 and the back electrode 24 on the left end of the battery cell 22a similar to the conductive layer 32 which is described later.

In the submodule 52c illustrated in FIG. 7, the back electrode 24 of the battery cell 22a at one end (on the left side in the drawing) of the power generation layer 20a has a similar lead wire attached thereto to provide a positive (+) terminal, and the transparent electrode 28 of the battery cell 22b at the other end (on the right side in the drawing) of the power generation layer 20a has a similar lead wire attached thereto to provide a negative (−) terminal, and the back electrode 24 of the battery cell 30 disposed in the center or substantially the center is electrically connected (shorted) to the metal substrate 12 that is grounded through the conductive layer 32.

Note that the battery cells 22 and 30 have the shape of a linear strip extending parallel to each other along one side of the rectangular metal substrate 12 in the direction perpendicular to the cross section illustrated in FIGS. 3, 5, and 7 (the direction perpendicular to the FIGS. 3, 5, and 7 drawings). Accordingly, the back electrodes 24 and the transparent electrodes 28 are also electrodes in the form of a strip that is long in the direction parallel to the one side of the metal substrate 12.

The solar cells (photoelectric conversion elements) 22 according to this embodiment are integrated type CIGS solar cells (CIGS photoelectric conversion elements) and have a configuration such that the back electrodes 24 are molybdenum electrodes, the photoelectric conversion layers 26 are made of CIGS, and the transparent electrodes 28 are made of ZnO. The buffer layers, when they are formed, are made of CdS. The grounding solar cell 30 has also a similar configuration.

The solar cells 22 and 30 may be fabricated by any of the known methods used to fabricate CIGS solar cells. One may use a laser scribing method or a mechanical scribing method to form the linear groove portions such as the gaps 25 between the back electrodes 24, the grooves 27 formed in the photoelectric conversion layers 26 and reaching the back electrode 24, and the opening 29 reaching to the back electrode 24 for separation from adjacent blocks of a photoelectric conversion layer 26 and a transparent electrode when the photoelectric conversion layer 26 and transparent electrode are integrated.

When light enters the battery cells 22 and 30 from the side of the transparent electrodes 28 in the submodules 52a through 52c of the solar cell modules 10a through 10c of the present invention, the light passes through the transparent electrodes 28 and the buffer layers (not shown) and reaches the photoelectric conversion layers 26 to generate electromotive force, thus producing a current flowing, for example, from the transparent electrodes 28 to the back electrodes 24. Note that the arrows shown in FIGS. 3, 5, and 7 indicate the direction of the current, and the direction in which electrons move is opposite to that of the current. Accordingly, the back electrode 24 of the leftmost solar cell 22a in FIGS. 3, 5, and 7 has a positive (plus or +) polarity and the transparent electrode 28 on the right side of the solar cell 22b has a negative (minus or −) polarity.

The components of the solar cells 22 and 30 forming the power generation layers 20 will be described below.

The back electrodes 24 and the transparent electrodes 28 in the solar cells 22 and 30 are both provided to extract current generated by the photoelectric conversion layers 26. Both the back electrodes 24 and the transparent electrodes 28 are each made of a conductive material. The transparent electrodes 28 provided on the incident light side must have translucency.

The back electrodes 24 are formed of, for example, Mo, Cr or W, or a material composed of a combination of these elements. The back electrodes 24 may have a single-layer structure or a laminated structure such as a two-layer structure.

The back electrodes 24 have preferably a thickness of 100 nm or more, and more preferably 0.45 to 1.0 micrometers.

The back electrodes 24 may be formed by any vapor-phase film deposition methods such as electron beam vapor deposition or sputtering.

The transparent electrodes 28 are formed, for example, of ZnO, ITO (indium tin oxide), or SnO₂, or a material composed of two or more of these oxides. The transparent electrodes 28 may have a single-layer structure or a laminated structure such as a two-layer structure. The thickness of the transparent electrodes 28, which is not specifically limited, is preferably 0.3 to 1.0 micrometers.

The method for forming the transparent electrodes 28 is not specifically limited, and they may be formed by any vapor-phase film deposition method as appropriate, such as electron beam vapor deposition and sputtering.

An anti-reflection coating such as one made of MgF₂ may be formed on the transparent electrodes 28.

The buffer layers are provided to protect the photoelectric conversion layers 26 when forming the transparent electrodes 28 and allow the light entering the transparent electrodes 28 to transmit to the photoelectric conversion layers 26.

The buffer layers are formed, for example, of CdS, ZnS, ZnO, ZnMgO, or ZnS (O, OH) or a material composed of two or more of these compounds.

The buffer layers preferably have a thickness of 0.03 to 0.1 micrometers. The buffer layers are formed by any appropriate method including the chemical bath deposition (CBD) method and the solution growth method.

Note that there may be provided a high-resistance film formed of, for example, ZnO between the buffer layers made of CBD-CdS or the like and the transparent electrodes 28 made of ZnO:Al or the like.

The photoelectric conversion layers 26 are photoelectric conversion semiconductor layers that absorb the incoming light from the transparent electrodes 28 through the buffer layers to generate current. According to this embodiment, the photoelectric conversion layers 26 are not specifically limited in configuration; they are preferably formed of, for example, at least one kind of compound semiconductor with a chalcopyrite structure as a main component of the photoelectric conversion semiconductor. The photoelectric conversion layers 26 may be formed of at least one kind of compound semiconductor composed of a group Ib element, a group IIIb element, and a group VIb element as a main component of the photoelectric conversion semiconductor.

For high optical absorbance and high photoelectric conversion efficiency, the photoelectric conversion layers 26 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te as main components of the photoelectric conversion semiconductor. Examples of such compound semiconductors include CuAlS₂, CuGaS₂, CuInS₂, CuAlSe₂, CuGaSe₂, CuInSe₂(CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ) Se₂(CIGS), Cu (In₁₋ₓAlₓ) Se₂, Cu (In₁₋ₓGaₓ) (S, Se)₂, Ag(In₁₋ₓGaₓ)Se₂, and Ag(In₁₋ₓGaₓ) (S,Se)₂.

The photoelectric conversion layers 26 preferably contain CuInSe₂(CIS) and/or Cu(In,Ga)Se₂(CIGS), which is obtained by dissolving Ga in the former. CIS and CIGS are semiconductors each having a chalcopyrite crystal structure, which reportedly have high optical absorbance and high photoelectric conversion efficiency. Further, they have little deterioration of efficiency under exposure to light and other circumstances, and exhibit excellent durability.

The photoelectric conversion layer 26 contains impurities for obtaining the desired semiconductor conductivity type. Impurities may be added to the photoelectric conversion layer 26 by diffusion from adjacent layers and/or direct doping into the photoelectric conversion layer 26. There may be a concentration distribution of constituent elements of group semiconductors and/or impurities in the photoelectric conversion layer 26, which may contain a plurality of layer regions formed of materials having different semiconductor properties such as n-type, p-type, and i-type.

For example, in a CIGS semiconductor, when provided with a distribution in the amount of gallium in the direction of thickness in the photoelectric conversion layer 26, the band gap width, carrier mobility and the like can be controlled, and thus high photoelectric conversion efficiency is achieved.

The photoelectric conversion layers 26 may contain one, or two or more kinds of semiconductors other than group semiconductors. Such semiconductors other than group I-III-VI semiconductors include a semiconductor formed of a group IVb element such as Si (group IV semiconductor), a semiconductor formed of a group IIIb element and a group Vb element (group III-V semiconductor) such as GaAs, and a semiconductor formed of a group IIb element and a group VIb element (group II-VI semiconductor) such as CdTe. The photoelectric conversion layers 26 may contain optional components other than a semiconductor and impurities used to obtain a desired conductivity type, provided that no detrimental effects are thereby produced on the properties.

The photoelectric conversion layers 26 may contain a group semiconductor in any amount as deemed appropriate. The content of group semiconductor contained in the photoelectric conversion layers 26 is preferably 75 mass % or more and, more preferably, 95 mass % or more and, most preferably, 99 mass % or more.

According to this embodiment, when the photoelectric conversion layers 26 are CIGS layers, the CIGS layers may be formed by such known film deposition methods as 1) multi-source evaporation methods, 2) selenization method (selenization/sulfidization method), 3) sputtering method, 4) hybrid sputtering method, and 5) mechanochemical processing method.

1) Known multi-source co-evaporation methods include: the three-stage method (J. R. Tuttle et al., Mat. Res. Soc. Symp. Proc., Vol. 426 (1966), p. 143, etc.), and the co-evaporation method of the EC group (L. Stolt et al.: Proc. 13th ECPVSEC (1995, Nice), 1451, etc.).

According to the former three-stage method, firstly, In, Ga, and Se are simultaneously evaporated under high vacuum at a substrate temperature of 300 degree C., which is then increased to 500 to 560 degree C. to simultaneously vapor-deposit Cu and Se, whereupon In, Ga, and Se are simultaneously evaporated. The later co-evaporation method by EC group is a method which involves evaporating copper-excess GIGS in the earlier stage of evaporation, and evaporating indium-excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked Se (a pre-printed collection of speeches given at the 68th Academic Lecture by the Japan Society of Applied Physics) (Autumn, 2007, Hokkaido Institute of Technology), 7P-L-6, etc.);
c) Method using radicalized Se (a pre-printed collection of presentations given at the 54th Academic Lecture by the Japan Society of Applied Physics) (Spring, 2007, Aoyama Gakuin Univ.), 29P-ZW-10, etc.); and
d) Method using a light excitation process (a pre-printed collection of speeches given at the 54th Academic Lecture by the Japan Society of Applied Physics) (Spring, 2007, Aoyama Gakuin Univ.), 29P-ZW-14, etc.).

2) The selenization method is also called the two-stage method, whereby, firstly, a metal precursor formed of a laminated film such as a Cu layer/In layer or a (Cu—Ga) layer/In layer is formed by sputter deposition, vapor deposition, or electrodeposition, and the film thus formed is heated in selenium vapor or hydrogen selenide to a temperature of 450 to 550 degree C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells, 35 (1994), 204-214, etc.); and a method in which selenium is sandwiched between thin metal films (e.g., as in Cu layer/In layer/Se layer Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap CIGS film is a method which involves first depositing a Cu—Ga alloy film, depositing an In film thereon, and selenizing with a Ga concentration gradient in the film thickness direction by making use of natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputter deposition techniques include: a technique using CuInSe₂ polycrystal as a target, one called two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and a technique called three-source sputtering method, whereby a Cu target, an In target, and an Se or CuSe target are sputtered in Ar gas, is known (T. Nakada et al., Jpn. J. Appl. Phys., 32 (1993), L1169-L1172, etc.).

4) Exemplary known methods for hybrid sputtering include one in which Cu and In metals are subjected to DC sputtering, while only Se is vapor-deposited in the aforementioned sputter deposition method (T. Nakada, et al., Jpn. Appl. Phys., 34 (1995), 4715-4721, etc.).

5) An exemplary method for mechanochemical processing includes a method in which a material selected according to the CIGS composition is placed in a planetary ball mill container and mixed by mechanical energy to obtain CIGS powder, which is then applied to a substrate by screen printing and annealed to obtain a CIGS film (T. Wada et al., Phys. stat. sol. (a), Vol. 203 (2006), p. 2593, etc.).

Other exemplary methods for forming CIGS films include screen printing, close-spaced sublimation, MOCVD and spraying. For example, crystals with a desired composition can be obtained by a method which involves forming a fine particle film containing a group Ib element, a group IIIb element, and a group VIb element on a substrate by, for example, screen printing or spraying and subjecting the fine particle film to pyrolysis treatment (which may be a pyrolysis treatment carried out under a group VIb element atmosphere) (JP 9-74065 A, JP 9-74213 A, etc.).

Although the solar cells 22 and 30 of the submodules 52a through 52c described above are integrated CIGS solar cells, the present invention is not limited thereto. The solar cells of the solar cell submodules according to the present invention (photoelectric conversion device, particularly the photoelectric conversion layers formed thereof) may, for example, be amorphous silicon (a-Si) based solar cells, tandem structure solar cells (a-Si/a-SiGe tandem structure solar cells), series-connected structure (SCAF) solar cells (a-Si series-connected structure solar cells), CdTe (cadmium telluride) based solar cells, thin-film silicon solar cells, dye-sensitized solar cells, organic solar cells, substrate solar cells, or superstrate solar cells.

Although the submodules 52a through 52c illustrated in FIGS. 3, 5, and 7 have a positive polarity (+polarity) on the side where the back electrodes 24 are located and a negative polarity (− polarity) on the side where the transparent electrodes 28 are located, the present invention is not limited thereto. Depending upon the solar cells, the submodules 52a through 52c may have a positive polarity (+polarity) on the side where the back electrodes 24 are located and a negative polarity (− polarity) on the side where the transparent electrode 28 is located.

For example, where the solar cells 22 and 30 are formed of tandem structure solar cells (a-Si/a-SiGe tandem structure solar cells), one may use a configuration such that, for example, each back electrode 24 is an electrode having a laminated Ag (silver) and ZnO layer structure, each transparent electrode 28 is formed of ITO, each photoelectric conversion layers 26 is formed, for example, of a laminated layer structure comprising an n-type semiconductor layer, an intrinsic semiconductor layer such as a microcrystalline silicone layer and an amorphous silicon germanium (a-SiGe) layer, and a p-type semiconductor layer disposed on each other, further comprising disposed thereon an n-type semiconductor layer, an intrinsic semiconductor layer such as an amorphous silicon (a-Si) layer, and a p-type semiconductor layer.

Where the solar cells 22 and 30 are formed of CdTe based solar cells, each photoelectric conversion layer 26 may be formed, for example, of a photoelectric conversion layer of a so-called CdTe (cadmium telluride) type.

Described below is the conductive layer 32 of the grounding solar cell 30 in the conductive layer 20a of the submodule 52c illustrated in FIG. 7.

The conductive layer 32 is disposed in lieu of the insulation layer 14 between the metal substrate 12 and the back electrode 24 in the grounding solar cell 30. The conductive layer 32 is conductive and electrically connects the back electrode 24 to the grounded metal substrate 12 to short them.

The conductive layer 32 is formed by a mixture of components, including the aluminum component of the aluminum base material of the metal substrate 12, the anodized film component of the insulation layer 14, and the back electrode 24 to attain a conductive property.

In the example illustrated in FIG. 7, the conductive layer 32 is formed only beneath the back electrode 24 of the grounding solar cell 30 and not formed beneath the gap 25, thus leaving the insulation layer 14. The present invention is not limited to such a configuration, however. The conductive layer 32 may be formed to extend also beneath the gap 25 and beneath the back electrode 24 of the adjacent solar cell 22 if it is within the grounding solar cell 30. In this case, however, the back electrode 24 of the grounding solar cell 30 and the back electrode 24 of the adjacent solar cell 22 are short-circuited so that the grounding solar cell 30 does not contribute to power generation.

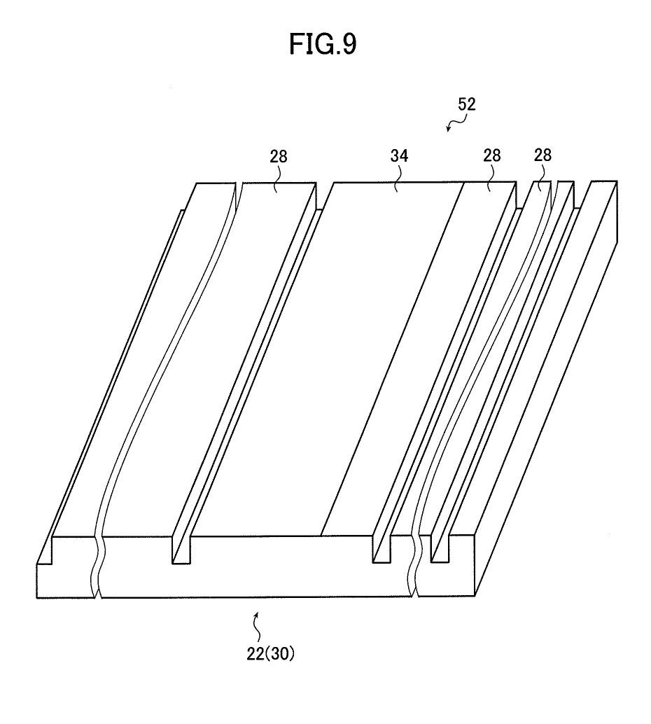

Such a conductive layer 32 may, for example, be formed as follows: the submodules 52a and 52b illustrated in FIGS. 3 and 5 are fabricated without shorting the metal substrate 12 with the transparent electrode 28 and the back electrode 24; an ultrasonic solder 34 is then applied to the transparent electrode 28 of the solar cell 22 of which the grounding solar cell 30 is to be formed as illustrated in FIG. 9; the thermal ultrasonic treatment is applied only to the solar cell 22 coated with the ultrasonic solder 34 to destroy the insulation layer 14 corresponding to the section of the solar cell 22 coated with the ultrasonic solder 34 and melt and mix the surfaces of the metal substrate 12 and the back electrode 24 that were in contact with the destroyed insulation layer 14, thus bringing the metal substrate 12, the back electrode 24, and the destroyed insulation layer 14 into a mixed state. The creation of the mixed state of the conductive layer 14, while not made clear, is assumed to take place as follows: for example, the thermal ultrasonic treatment applied only to the solar cell 22 coated with the ultrasonic solder 34 destroys the insulation layer 14 corresponding to the section of the solar cell 22 coated with the ultrasonic solder 34 to produce small gaps to make it porous, while melting the surfaces of the metal substrate 12 and the back electrode 24 that were in contact with the destroyed insulation layer 14 allows the melt to enter the small gaps formed in the destroyed insulation layer 14. If the transparent electrode 28 and the photoelectric conversion layer 26 of the grounding solar cell 30 are also destroyed, the conductive layer 32 formed may also contain mixed therein these destroyed layers and the ultrasonic solder 34. The solder may be applied over the whole cell or, as illustrated in FIG. 3, the transparent electrode 28 may be left intact for one side or for both sides. Rather than by spreading, solder may be linearly deposited sequentially on the cell while supplying the solder. From the viewpoint of manufacture, however, it is preferable that linearly deposited solder is applied simultaneously after being deposited, or soldering is conducted simultaneously in a plurality of linear deposits.

The conductivity of the conductive layer 32 thus formed may be considered to depend upon the state of mixture of the conductive layer 32. Accordingly, the conductivity of the conductive layer 32 may be controlled and a required conductivity may be obtained by appropriately controlling the amount of the ultrasonic solder 34 applied and, in the thermal ultrasonic treatment, the temperature of heat applied, the time during which the heat is applied, the magnitude of ultrasonic wave applied, and the length of time of the thermal ultrasonic treatment, according to the configuration and functions of the solar cell 22 of which the grounding solar cell 30 is to be formed as well as the necessity of power generation function, etc., especially the thickness of the insulation layer 14.

One may carry out experiments, simulations, and the like to predetermine the relationships between the conductivity of the conductive layer 32; the configuration and functions of the solar cell 22, especially the thickness of the insulation layer 14 and the like; and the amount of the ultrasonic solder 34, the temperature of heat applied in the thermal ultrasonic treatment, the heating time, the ultrasonic wave strength and the thermal ultrasonic treatment time.

In the above example, as shown in FIG. 7, the conductive layer 32 is formed after the submodules 52a and 52b have been manufactured as shown in FIGS. 3 and 5 without shorting the metal substrate 12 with the transparent electrode 28 and the back electrode 24, but the present invention is not limited in this way. The conductive layer 32 may be formed at any stage of the submodule fabrication process, provided that the insulation layer 14 is formed on the metal substrate 12.

The solar cell module may be fabricated, for example, in such a sequence that the ultrasonic solder is applied to a given section of a solar cell, of which the grounding solar cell 30 is to be formed, on the insulation layer 14 on the metal substrate 12, followed by thermal ultrasonic treatment to form the conductive layer 32 where the destroyed insulation layer 14, the metal substrate 12, and the ultrasonic solder are mixed, whereupon a plurality of solar cells 22 and the grounding solar cell 30 may be formed. Alternatively, one may follow a sequence such that after the back electrode 24 is formed on the insulation layer 14 of the metal substrate 12, the ultrasonic solder is applied to the back electrode 24 of a given section of a solar cell where the grounding solar cell 30 is to be formed, to form the conductive layer 32 where the destroyed insulation layer 14, the metal substrate 12 and the back electrode 24 are mixed, or further to form the conductive layer 32 where the ultrasonic solder is further mixed, whereupon the photoelectric conversion layer 26 and the transparent electrode 28 are thereon formed sequentially, thereby to form a plurality of solar cells 22 and the grounding solar cell 30. Alternatively, the conductive layer 32 may be likewise formed after forming the photoelectric conversion layer 26, followed by formation thereon of the transparent electrode 28, whereupon a plurality of solar cells 22 and the grounding solar cell 30 may be thereon formed.

According to any of these methods, the solar cells 22 are completed after the conductive layer 32 is formed and, therefore, at least one of the back electrode 24, the photoelectric conversion layer 26, and the transparent electrode 28 needs to be formed, which requires accurate alignment. Thus, the conductive layer 32 is formed preferably after the solar cells 22 are formed.

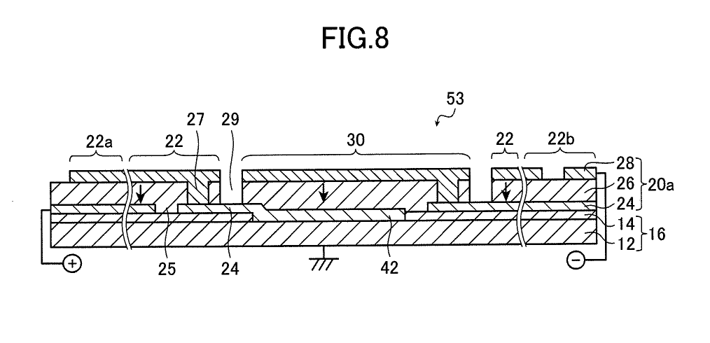

Note that the submodule 53 illustrated in FIG. 8 can be used in place of the submodule 52c illustrated in FIG. 7.

FIG. 8 is a cross-section view schematically illustrating the submodule 53 used in module 10c of the present invention.

The submodule 53 of the embodiment illustrated in FIG. 8 has the same configuration as the submodule 52c illustrated in FIG. 7 except that a conductive layer 42 of the grounding solar cell 30 has a different configuration. Thus, same components are given same reference characters, and a detailed description thereof will be omitted.

In the submodule 53 as illustrated in FIG. 8, the back electrode 24 extending from a neighboring solar cell 22 is disposed directly between the metal substrate 12 and the photoelectric conversion layer 26 to form the conductive layer 42 in lieu of the conductive layer 32 of the grounding solar cell 30 of the submodule 52c illustrated in FIG. 7. Since the back electrode 24 and the grounded metal substrate 12 are thus in direct contact and electrically connected with each other in the submodule 53 of this embodiment, the back electrode 24 of the grounding solar cell 30 can be grounded through the metal substrate 12.

Thus, the solar cells 22 and 30 of the solar cell module 40 according to this embodiment may of course have any configurations as appropriate (photoelectric conversion device, photoelectric conversion layer) as may the solar cell module 10 described above.

The submodule 53 comprising such a conductive layer 42 may be configured using the support substrate 16 that is not provided with the insulation layer 14, such as an anodized film, in an area corresponding to the grounding solar cell 30 but provided with the insulation layer 14, such as an anodized film on the metal substrate 12 such as the Al substrate, in the other area, following a procedure of forming the power generation layer 20, that is, the back electrode 24 and the conductive layer 42, the photoelectric conversion layer 26 and the buffer layer, and the transparent electrode layer 28 are formed sequentially, to form a plurality of solar cells 22 and the grounding solar cell 30 as in the case of the submodule 52c described above. This is how the submodule 53 according to this embodiment is formed.

In lieu of the support substrate 16 including the metal substrate 12 that is not provided with the insulation layer 14 only in the region corresponding to the grounding solar cell 30, one may use the support substrate 16 where the insulation layer 14 is formed over the whole surface of the metal substrate 12 such as an anodized aluminum substrate, and where a part of the insulation layer 14 such as an anodized film located in a region corresponding to the grounding solar cell 30 is removed by scribing, etching, or other means, and likewise form the power generation layer 20 by a process starting with vapor deposition of the back electrode 24 to construct the submodule 53 according to the embodiment.

The method of manufacturing the submodule of the present invention shown in FIG. 7 will be described below.

FIG. 10 is a flow chart showing an example of a method for manufacturing the submodule illustrated in FIG. 7.

As illustrated in FIG. 10, an aluminum substrate is used as the metal substrate 12, which is subjected to anodization processing by the method described above to form an anodized film that serves as the insulation layer 14 on the surface so that an aluminum substrate having an anodized film is formed, thus providing the support substrate 16 (step S100).

Needless to say, it may be allowed that an aluminum substrate having an anodized film is prepared beforehand as the support substrate 16.

Next, a Mo film is formed on the insulation layer 14 of the support substrate 16 by any known film deposition method such as DC magnetron sputtering technique (step S102).

Then, the Mo film thus formed on the insulation layer 14 is cut by the laser scribing method and patterned to a pattern 1 to form the gaps 25 and the back electrodes 24 (step S104).

Then, CIGS based compound semiconductor films (p-type CIGS based light absorption films), which serve as the photoelectric conversion layers 26, are formed on the back electrodes 24 formed on the insulation layers 14 by any of the known methods described above such as the selenization/sulfidization method or a multi-source evaporation method in such a manner as to fill the gaps 25 (step S106).

Subsequently, CdS films that are to serve as buffer layers (n-type high-resistance buffer layers) are formed on the thus formed CIGS based compound semiconductor films by any of the known methods described above such as the CBD technique (step S108).

Next, the CIGS based compound semiconductor films and the CdS films thus formed on the back electrodes 24 are cut as a whole by the mechanical scribing method described above and patterned to a pattern 2 to form the grooves 27 reaching the back electrode 24, thus forming the photoelectric conversion layer 26 and the buffer layer (step S110).

Then, ZnO films (n-type ZnO transparent conductive film window layer), of which the transparent electrode layer 28 is to be made, are formed by any of the known methods described above such as the MOCVD method or RF sputtering method on the thus formed buffer layers (photoelectric conversion layers 26) in such a manner as to fill the grooves 27 (step S112).

Next, the ZnO films, the buffer layers, and the photoelectric conversion layers 26 thus formed are cut as a whole by the mechanical scribing method described above and patterned to a pattern 3 to form openings 29 reaching the back electrodes 24 between adjacent solar cells 22 and separately provide the photoelectric conversion layer 26, the buffer layer, and the transparent electrode layer 28 in each solar cell 22, thereby forming a plurality of solar cells 22 (step S114).

Then, the ultrasonic solder 34 is applied onto the transparent electrode layer 28 of a solar cell 22 allocated beforehand to form the grounding solar cell 30 (step S116). Then, the transparent electrode layer 28 of the solar cell 22 coated with the ultrasonic solder 34 is selectively subjected to thermal ultrasonic treatment to destroy its insulation layer 14 and mix the components of the metal substrate 12 and those of the back electrode 24 to form the conductive layer 32 (step S118).

Thus, the submodule 52c according to the embodiment is formed (step S118).

Note that when manufacturing the submodules 52a and 52b illustrated in FIGS. 3 and 5 using the method for manufacturing the submodule illustrated in FIG. 10, in step S114, the submodule 52a may be formed by forming the plurality of solar cells 22 on the support substrate 16 and subsequently forming the conductive layer on, and thus short-circuiting, the metal substrate 12 and the transparent electrode 28 on the right end of the power generation layer 20, and the submodule 52b may be formed by forming the plurality of solar cells 22 and thereafter forming the conductive layer on, and thus short-circuiting, the metal substrate 12 and the back electrode 24 on the left end of the power generation layer 20.

The solar cell devices 50a through 50d of the present invention illustrated in FIGS. 1A to 1D, the conventional solar cell device 50e illustrated in FIG. 1E, and a conventional solar cell device without a metal substrate were manufactured as working examples 1 to 4, and comparison examples 1 and 2.

Integrated CIGS solar cell submodules with 155 cells (solar cells 22) connected in series on the insulation layer 14 of the metal substrate 16 with an insulation layer were manufactured using aluminum subjected to surface anodization treatment and a clad stainless steel material as the metal substrate with an insulation layer 16. This submodule was sandwiched between ETFE (tetrafluoroethylene (C₂F₄) and ethylene (C₂H₄) copolymer) and galvanic steel plate using EVA as an adhesive material to produce solar cell modules measuring 90×60 cm. The generated voltage of the solar cell module was approximately 100 V.

In the obtained solar cell modules, the power generation layer 20 or 20a of the submodules and the metal substrate 12 were connected on the high potential side, the low potential side, and the intermediate potential side, or not connected as submodules 52a, 52b, 52c, and 52e, respectively. The these submodules were used to manufacture the solar cell devices 50a through 50d of working examples 1 through 4, and the solar cell device 50e of comparison example 1.

The thickness of the aluminum anodized film that would form the insulation layer 14 in the working examples 1 through 4 was 20 micrometers, and the thickness of the aluminum anodized film that would form the insulation layer 14 in the comparison example 1 was 100 micrometers in consideration of the dielectric strength voltage.

The potential difference (maximum value) of the anodized film acting as the insulation layer 14 of the prepared working examples 1 through 4 and the comparison examples 1 and 2, and the voltage (maximum value) between the metal substrate 12 and the module outer frame (metallic outer frame 54) were measured. The obtained results are shown in Table 1 below.

TABLE 1

| | | | Anodized | Voltage (max |
|---|---|---|---|---|
| | | | film | value) between |
| | Circuit/Metal | Anodized | potential | metal substrate |
| | substrate | film | difference | and module |
| | connection | thickness | (max value) | outer frame |
| Working | Low | 20 | 100 V | 200 V |
| Example 1 | potential | micrometers | | |
| | side | | | |
| Working | High | 20 | 100 V | 200 V |
| Example 2 | potential | micrometers | | |
| | side | | | |
| Working | Midpoint | 20 | 50 V | 150 V |
| Example 3 | potential | micrometers | | |
| Working | Low | 20 | 100 V | 100 V |
| Example 4 | potential | micrometers | | |
| | side | | | |
| | High | 20 | 100 V | 100 V |
| | potential | micrometers | | |
| | side | | | |
| Comparison | None | None | 400 V | 200 V |
| Example 1 | | | | |
| Comparison | None (no | — | — | 200 V |
| Example 2 | metal | | | |
| | substrate) | | | |

As can be understood from the result shown in Table 1, because the potential difference of the anodized film acting as the insulation layer 14 can be substantially reduced, the thickness of the Al anodized film acting as the insulation layer 14 can be thinner in the working examples 1 through 4 compared to the comparison example 1.

Furthermore, the voltage between the metal substrate 12 and the module outer frame (metallic outer frame 54) can be substantially lower in the working examples 3 and 4 compared to the comparison examples 1 and 2.

Note that working example 3 has the best performance for the potential difference of the anodized film acting as the insulation layer 14, but working example 4 has the best performance for the voltage between the metal substrate 12 and the metallic outer frame 54.

Although a metal substrate with an insulation layer composed of an anodized film formed as an insulation film on at least one surface of an aluminum (Al) base was used as the metal substrate with an insulation layer in the embodiments described above, it need not be said that the present invention is not limited to this, as mentioned above. Other than aluminum plate, the metal substrate used in the present invention may be made of aluminum-clad material, stainless steel plate, steel plate or the like; other than aluminum base, the metal base may be made of any one base material of silicon, titanium, iron; other than aluminum anodized film, the insulation layer may be made of any one oxide film, nitride film, or oxynitride film of aluminum, silicon, titanium, and iron. In this case, the withstand voltage required by the insulation layer can be reduced.

The device configured by the photoelectric conversion semiconductor in the above embodiments is a thin film solar cell that uses at least one kind of compound semiconductor of a chalcopyrite structure, that is, a photoelectric conversion semiconductor having as a main component a group I, III, or VI element based chalcopyrite type compound semiconductor. However, needless to say, the present invention is not limited to this. The device configured by the photoelectric conversion semiconductor that can be used in the present invention is not limited to chalcopyrite based compound semiconductors inasmuch as the device may also be configured by CIS-CIGS based thin film solar cells, thin film silicon based thin film solar cells, CdTe based thin film solar cells, group III-V based thin film solar cells, dye-sensitized thin film solar cells, and organic thin film solar cells. The withstand voltage required by the insulation layer in such configured thin film solar cells can be reduced.

Although the metal substrate is directly connected to the high voltage potential side, low potential side, or midpoint (average) potential side in the solar cell module in the above embodiments in order to fix the potential of the metal substrate, the present invention is not limited to this configuration. The potential of the metal substrate may also be set from the partial potential ratio of the resistance when the metal substrate is connected through the electrical resistance between two points of different potential within the solar cell module. Since the electrical resistance consumes the power of the solar cell, it is permissible to use a resistance sufficiently high to the degree that minimizes the power consumed by the resistance so as to be negligible.

The solar cell module and the solar cell device of the present invention are basically configured as described above.

While the solar cell module and solar cell device of the present invention have been described above in detail with reference to various embodiments, the present invention is by no means limited to those embodiments, and various improvements or modifications may be made without departing from the scope and spirit of the present invention.

What is claimed is:

1. A solar cell module, comprising:
a metal substrate with an insulation layer having a metal base and said insulation film formed on at least one side of said metal base; and
a semiconductor circuit provided on said metal substrate,
wherein said metal base is connected to a predetermined part of an electric path having a first potential between a minimum potential and a maximum potential of said semiconductor circuit, and a potential of said metal base is maintained at said first potential of said part of said electric path of said semiconductor circuit when said semiconductor circuit is operating.

2. The solar cell module according to claim 1, wherein said semiconductor circuit is connected in series and/or parallel.

3. The solar cell module according to claim 1, wherein, when a minimum potential side of said semiconductor circuit is connected to a ground side of a solar cell device configured by one or more solar cell modules, said metal base within said solar cell module is connected to a part of said semiconductor circuit having a potential that is lower than an average potential of said semiconductor circuit.

4. The solar cell module according to claim 3, wherein said metal base is shorted to said part of said semiconductor circuit that has the lowest potential when said semiconductor circuit is operating.

5. The solar cell module according to claim 1, wherein said metal base within said solar cell module in which a minimum potential side of said semiconductor circuit is connected to a ground side of a solar cell device configured by one or more solar cell modules is connected to a part of said semiconductor circuit having a potential that is higher than an average potential of said semiconductor circuit.

6. The solar cell module according to claim 5, wherein said metal base is shorted to said part of said semiconductor circuit that has the highest potential when said semiconductor circuit is operating.

7. The solar cell module according to claim 5, wherein said metal substrate is connected through two or more points having different potentials within said solar cell module via a electrical resistance in order to fix a potential of said metal substrate, and said potential of said metal substrate is fixed from a partial potential ratio of said electrical resistance.

8. The solar cell module according to claim 1, wherein said metal substrate is configured by an aluminum plate, a stainless steel plate or a steel plate, or an alloy plate or a clad plate incorporating these metals, said metal base is a metal base configured by any one of aluminum, silicon, titanium, and iron, and said insulation layer is configured by an oxide film, a nitride film, or an oxynitride film composed of any one of aluminum, silicon, titanium, and iron.

9. The solar cell module according to claim 1, wherein said metal substrate is configured by an aluminum plate, and said insulation layer is configured by an anodized film formed on at least one surface of said aluminum base.

10. The solar cell module according to claim 1, wherein said metal substrate is made of an aluminum clad material.

11. The solar cell module according to claim 1, wherein a semiconductor of said semiconductor circuit is a photoelectric conversion semiconductor that generates an electrical current by light absorption.

12. The solar cell module according to claim 11, wherein said photoelectric conversion semiconductor comprises as a main component at least one kind of a compound semiconductor having a chalcopyrite structure.

13. The solar cell module according to claim 12, wherein said main component of said photoelectric conversion semiconductor comprises at least one kind of compound semiconductor containing a group Ib element, a group IIIb element, and a group VIb element.

14. The solar cell module according to claim 13, wherein said main component of said photoelectric conversion semiconductor comprises at least one kind of compound semiconductor containing:
at least one kind of group Ib element selected from the group consisting of Cu and Ag,
at least one kind of group IIIb element selected from the group consisting of Al, Ga, and In, and
at least one kind of group VIb element selected from the group consisting of S, Se, and Te.

15. The solar cell module according to claim 11, wherein a device configured by said photoelectric conversion semiconductor comprises any one kind of thin-film solar cells selected from the group consisting of CIS-CIGS based thin-film solar cells, thin-film silicon based thin-film solar cells, CdTe based thin-film solar cells, group III-V based thin-film solar cells, dye-sensitized thin-film solar cells, and organic thin-film solar cells.

16. The solar cell module according to claim 11, further comprising a metallic outer frame or a protective metal plate supporting in an electrically insulated state said metal substrate with the insulation layer provided with said semiconductor circuit,
wherein said metallic outer frame or said protective metal plate is connected to a ground of a solar cell device configured by one or more solar cell modules.

17. The solar cell module according to claim 11, wherein said metallic outer frame or said protective metal plate supports said metal substrate with the insulation layer provided with said semiconductor circuit through an electrical insulation material.

18. A solar cell device, comprising:
at least one solar cell module according to claim 16.

19. The solar cell device according to claim 18, wherein said at least one solar cell module comprises a plurality of said solar cell modules, and when said plurality of the solar cell modules are connected in series, a connection portion of two solar cell modules connected in series is connected to said ground.
